(19) United States
(12) Patent Application Publication
(10) Pub. No.: US 2022/0017238 A1
(43) Pub. Date: Jan. 20, 2022

(54) PROCESS FOR RAPID RE-CONFIGURATION AND CUSTOMIZATION OF SMALL SATELLITES

(71) Applicant: NOVI LLC, Arlington, VA (US)

(72) Inventors: Amit Mehra, Arlington, VA (US); Scott Steffan, Hamburg, NY (US); Evan Sandler, Fairfax, VA (US)

(73) Assignee: NOVI LLC, Arlington, VA (US)

(21) Appl. No.: 17/372,477

(22) Filed: Jul. 11, 2021

Related U.S. Application Data
(60) Provisional application No. 63/053,946, filed on Jul. 20, 2020.

(51) Int. Cl. B64G 1/10; B64G 1/22; H04L 12/40

(52) U.S. Cl. CPC B64G 1/10; B33Y 10/00; H04L 12/40; B64G 1/22

(57) ABSTRACT

A process for rapid re-configuration and customization of small satellites using additively manufactured chassis customized to create a more conformal and integrated bus design adapted to a particular payload. The additional components or subsystems of the bus required are are integrated either on the sidewalls of the additively manufactured chassis, or as the sidewalls of such chassis, while the payload is also secured or integrated via custom features that are part of the additively manufactured chassis. Chassis can be rapidly reconfigured in the design stage to adapt to a preferred vendor's application, components and subsystems, or payload specifications, an engineering change to the bus and/or payload, responsive to test data, or the like, thereafter additively manufacturing a new chassis and rapidly producing the entire small satellite.

### RELATED APPLICATIONS

This application claims the benefit of U.S. provisional patent application Ser. No. 63/053,946 filed 20 Jul. 2020 by the same inventors.

### GOVERNMENT RIGHTS

This invention was made with U.S. Government support under agreement No. FA8649-2-9-9144, awarded by the U.S. Government. The U.S. Government has certain rights in this invention.

### FIELD OF ART

The present invention relates to a process for additive manufacturing of small satellites. The present invention more particularly relates to rapid re-configuration and customizing of small satellite designs with responsive design and additive manufacturing.

### BACKGROUND OF THE INVENTION

Small satellites, including CubeSats, have come into increased use for a wide variety of Low Earth Orbit (LEO) missions. Small satellites are typically launched as secondary payloads on space launch vehicles carrying large satellites as their primary payload. Small satellite launchers are also in development and production, providing a means to launch CubeSats and other small satellites as primary payloads.

Small satellite dimensions have been standardized based on a 10 cm by 10 cm by 10 cm cube, representing one unit (1U). Traditionally, stacking or combining multiple 1U blocks have resulted in standard larger sizes as well, ranging from 1U up to 24U configurations.

Satellites are generally considered to be composed of a “bus” and one or more “payloads”. The payload(s) are the elements of the satellite that define the primary mission. The bus supports the payload(s) by providing structure, electrical power and thermal management, communications and data processing, Guidance, Navigation and Control (GNC), and other related elements so that the payload(s) can complete their in-space mission.

Additive manufacturing, also called 3D printing, turns a design stored in a computer into a physical object. By changing the stored design, the object to be created can be changed.

### SUMMARY OF THE INVENTION

The present invention provides an additive manufacturing process for rapidly making a wide variety of small satellites, with the novel advantages of improved or highly customized volume usage, increased payload volume or configurability, improved avionics standardization, and increased manufacturing speed. Other advantages include: eliminating the current limitation of using 1U, 3U and 6U building blocks to enable a light-weight and optimized custom structure that is tailored to be conformal to or combined with specific payload(s); creation of a single piece structure without fasteners and failure points to minimize overall part count, interfaces and assembly/integration time and labor; rapid creation of a flexible, “morphable” bus that can be used as an experimental test platform for responsive space missions; realization of a high-payload volume bus capable of accommodating multiple payloads within a compact form-factor; and integration into a high volume production environment.

### DESCRIPTION OF THE FIGURES OF THE DRAWINGS

The present invention will hereinafter be described in conjunction with the following drawing figures, wherein like numerals denote like elements, and:

FIG. 1 is a perspective diagrammatic view illustrating a prior art approach to building a small satellite;

FIG. 2 is a diagrammatic view illustrating an exemplary embodiment of a process for rapid configurability, additive design and manufacturing of small satellites, according to a preferred embodiment of the present invention;

FIG. 3 is a diagrammatic view illustrating an exemplary embodiment of a facility for implementing the exemplary process for reconfiguration and additive manufacturing of small satellites of FIG. 2, according to a preferred embodiment of the present invention; and

FIG. 4 is process flow chart view illustrating the exemplary embodiment of the process for reconfiguration and additive manufacturing of small satellites of FIG. 2, according to a preferred embodiment of the present invention.

### DETAILED DESCRIPTION OF THE INVENTION

Reference numerals have hundreds digits that are the figure numbers where the referenced item is first shown.

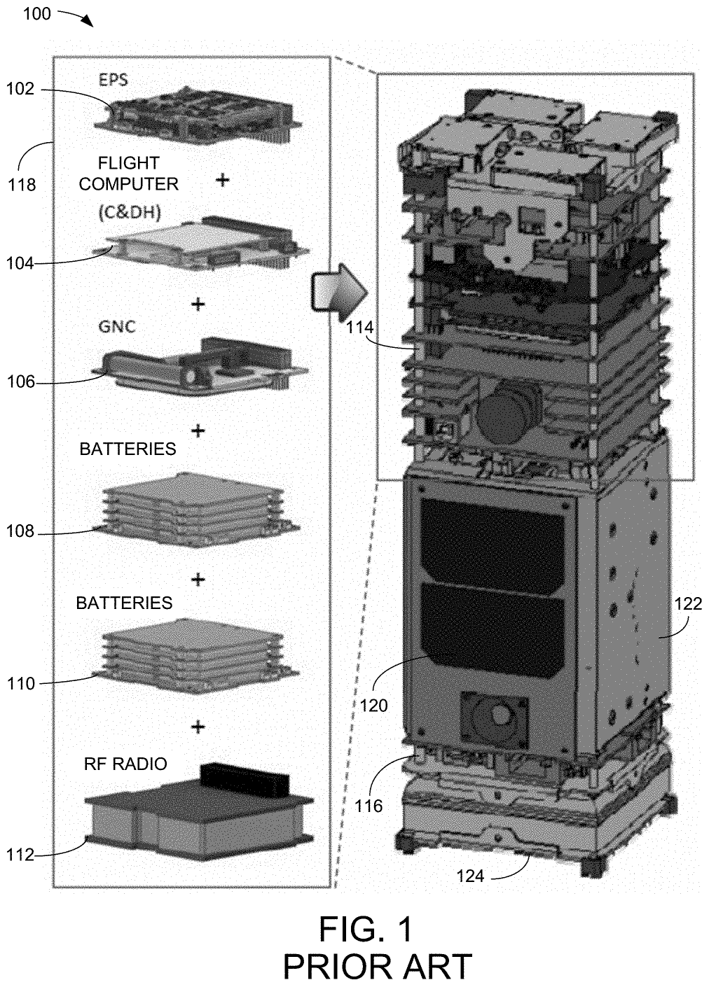

FIG. 1 is a perspective diagrammatic view illustrating a prior art approach to building a small satellite 100. In the prior art, components and subsystems included bus electronic elements 118 stacked on top of payload 122, threaded at the corners by rods 114 (one labeled of four used) which extended 116 through the payload 122 into the launch vehicle interface plate 124. The bus electronic elements 118 illustrated in FIG. 1 is not an exhaustive illustration of all possible bus electronic elements 118. Bus electronic elements 118 include, without limitation, multiple elements: an electrical power system 102, solar panels 120, and batteries 108 and 110 to supply power to the payload 122 and to bus electronic elements 118; the flight computer 104; the GNC system 106; and the radio 112. Also included in bus electronic elements 118 are cables and wiring (not shown) for connecting the illustrated bus electronic elements 118.

A disadvantage of the prior art is the use of frames, typically made of angle bar, being built up with fasteners, which is slow and not rapidly adaptive to design requirements for various payloads. It is also limited to specific configurations, with bus electronic elements 118 and electronics occupying a large fraction of the available volume, thereby limiting the amount of useful payload volume that is available for the mission.

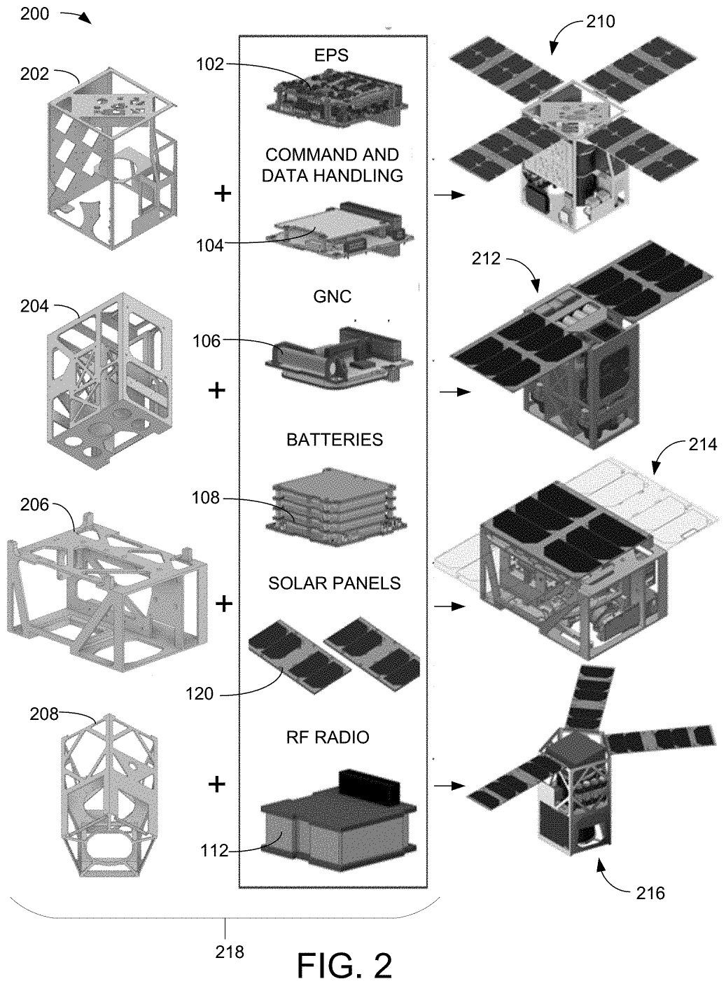

FIG. 2 is a diagrammatic view illustrating an exemplary embodiment of a process 200 for additive manufacturing of small satellites, according to a preferred embodiment of the present invention. The illustrated variety of chassis 202, 204, 206, and 208 is not a limitation on the various possible chassis additively manufactured for the process 200. Chassis 202 is a 2U chassis. Chassis 204 is a 4U chassis. Chassis 206 is another 4U chassis with a different orientation. Chassis 208 is a pentagonal 2U chassis. Each chassis 202, 204, 206, and 208 has fastener adaptations and conformal shape for attaching bus electronic elements 118 to and/or as side panels of the respective small satellite 210, 212, 214, and 216, thereby leaving a large volume of the interior core of the chassis 202, 204, 206, and 208 available for the payload(s). Small satellite 210 is built on chassis 202. Small satellite 212 is built on chassis 204. Small satellite 214 is built on chassis 206. Small satellite 216 is built on chassis 208. Any chassis 202, 204, 206, 208, or other chassis embodiment not illustrated, together with selected bus electronic elements 118 but minus the payload are a bus 218. The level of additive bus design and manufacturing customization also allows the design and positioning of each of these subsequent parts to further be integrated and optimized to maximize the useful payload space in the interior, or core, of the bus 218.

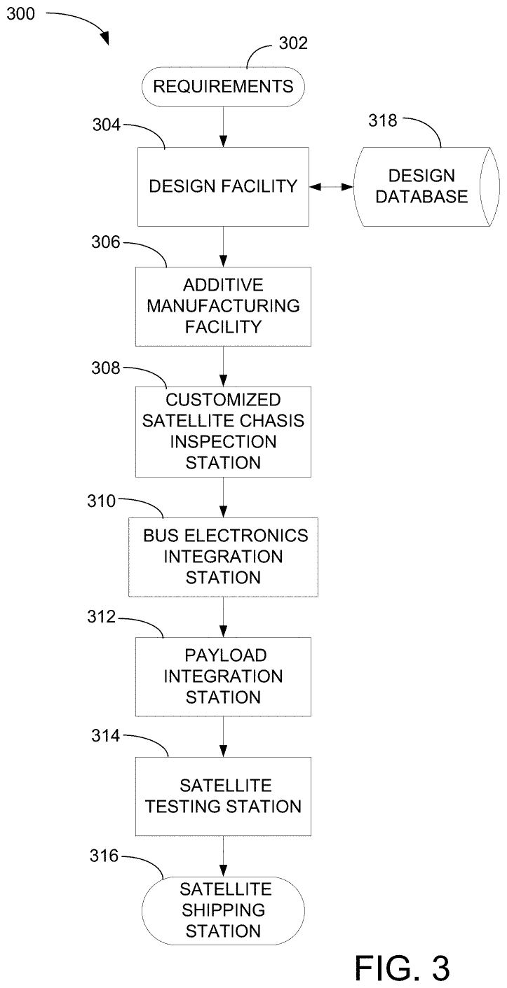

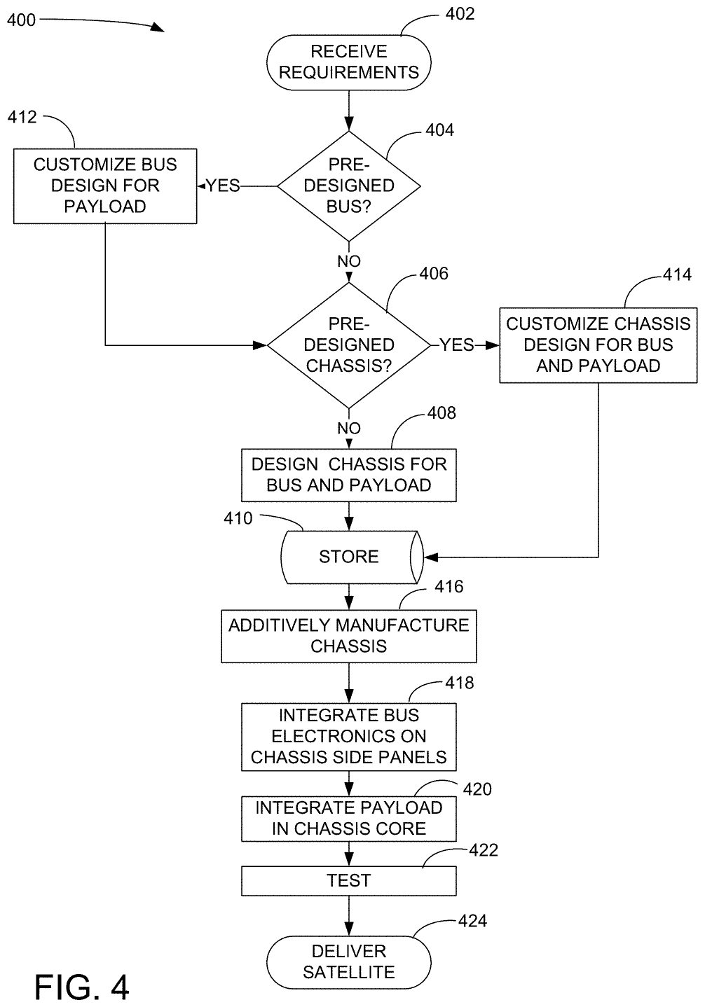

FIG. 3 is a diagrammatic view illustrating an exemplary embodiment of a facility 300 for implementing the exemplary process 400 (see FIG. 4) for rapid reconfiguration, additive design and manufacturing of small satellites 210, 212, 214, and 216 of FIG. 2, according to a preferred embodiment of the present invention. Requirements 302 include a wide range of parameters to which the satellite must conform to carry and serve the payload. For non-limiting examples, parameters may include payload volume and positioning, power, command, and data management, operating environment management, and the like. The requirements may be supplied by payload customers or may be developed in-house based on mission needs. The requirements are supplied to the design facility 304, a computer with software design tools for making models to be sent to the additive manufacturing facility 306. At times, a complete bus model may already be available in the design database 318. At other times, only a useful chassis model may be available. In some cases, a new bus 218 or chassis, such as, without limitation 202, 204, 206, or 208, model must be designed from the start using the design facility 304. All edited and new designs are saved in the design database 318.

Additive manufacturing facility 306 includes one or more 3D printers and/or additive manufacturing machines. The ability to additively manufacture various materials in additive manufacturing facility 306 may be achieved by having a plurality of such machines, each using a different material. Additive manufacturing facility 306 may be a single physical facility or may include additive manufacturing machines at a plurality of locations. The customized chassis produced by the additive manufacturing facility 306 is provided to the customized satellite chassis inspection station 308, where correct production is verified. The chassis is then transferred to the bus electronics integration station 310, where the bus electronic elements 118 are installed on the chassis, such as 202, 204, 206, or 208. This completes the assembly of the bus 218 of the small satellite, such as, without limitation, 210, 212, 214, and 216. The chassis 202, 204, 206, or 208 is then transferred again, to the payload integration station 312, where the payload is installed in the core of the chassis 202, 204, 206, or 208. This completes the assembly of the small satellite such as, without limitation, 210, 212, 214, or 216. Due to the high level of conformity enabled by the process, these steps, including payload integration, may occur at a common station.

The completed small satellite 210, 212, 214, 216, or other non-illustrated embodiment, is tested at the satellite testing station 314. Tests may include, without limitation, functional testing, performance testing, and environmental testing of subsystems and the integrated system. Upon successful testing, the small satellite 210, 212, 214, 216, or other non-illustrated embodiment, is sent to the satellite shipping station 316 for crating and shipping. In a particular embodiment, the functions of bus electronics integrations station 310 and payload integration station 312 may be intertwined.

FIG. 4 is process flow chart view illustrating the exemplary embodiment of the process 400 for rapid reconfiguration and additive manufacturing of small satellites, according to a preferred embodiment of the present invention. In step 402, a set of requirements 302 for a small satellite such as 210, 212, 214, 216 or custom satellite not illustrated, are received. Preferably, the requirements 302 are formatted in a predetermined format. The requirements 302 include all aspects of the small satellite 210, 212, 214, 216, or custom satellite not illustrated, design. In step 404, a determination is made as to whether or not a bus design that meets the requirements 302 is already available in design database 318. Preferably, the design database 318 associates a set of formatted requirements 302 with a particular small satellite bus design, allowing the design facility 304 to merely search design database 318 based on requirements 302 to find any pre-existing bus design having bus electronic elements 118 for supporting the payload. If there is no predesigned bus found in step 404, step 406 determines whether or not there is a pre-existing design for a chassis, such as, without limitation, chassis 202, 204, 206, and 208 that will satisfy requirements 302. This may be achieved by searching design database 318 with a subset of the formatted requirements 302 related to chassis requirements.

If there is no predesigned chassis 202, 204, 206, and 208 found in step 406, a new design for a chassis is created in step 408 and stored in design database 318 in step 410. A new chassis design from step 408 will be adapted to both the payload and the bus, including open spaces and connection points within the chassis. If a predesigned bus was found in step 404, the bus design is customized for the required payload in step 412. Customization of the bus design in step 412 may include, without limitation, selection of bus elements 118 from vendors, sizing of other components. Control and information then transfers to step 406. If a predesigned chassis is found in step 406, the chassis design is customized for the required bus and payload in step 414 and stored 410 in design database 318 as a new predesigned chassis.

In step 416, the chassis design is additively manufactured in additive manufacturing facility 306. The additively manufactured chassis 202, 204, 206, 208, or other chassis design not illustrated, is primarily a frame, on which bus electronic elements 118 will be attached to be supported on and/or become the side panels of the small satellite 210, 212, 214, 216, or respective other design. The additive manufacturing step 416 includes adaptations for fasteners and shaped cavities and indentations for bus electronic elements 118. Additive manufacturing step 416 may also include adaptations for additional use case needs, further integration of other subsystem elements, and accommodations for vehicle level integration. Additive manufacturing step 416 includes providing supports for the payload. Additive manufacturing provides the ability for other components or subsystems traditionally procured independently to be highly integrated and/or conformal to the additively manufactured chassis. Examples may include but are not limited to propulsion, launch vehicle mounting adapters, and launch and/or satellite separation systems.

In step 418, bus electronic elements 118 and any other required bus electronics not shown in FIGS. 1 and 2 are attached to the additively manufactured chassis 202, 204, 206, 208, or other chassis design, to be mounted on the small satellite 210, 212, 214, 216, or respective other design. Appropriate electrical connections are made. For any given function of a bus electronic elements 102, 104, 106, 108, 110, 112, 120, and 106, a number of vendors may be available, or new configurations may be developed. Additive manufacturing allows adaptation of the chassis to receive the preferred vendor's bus electronic elements 118 based on, for non-limiting examples, price, availability, interfaces, power requirements, and reliability.

In step 420, the payload is mounted within the small satellite core, using the supports additively manufactured into the chassis. In a particular embodiment, some bus electronic elements 118 may be installed after the payload is integrated. In some embodiments, more than one payload may be integrated with the chassis. Payloads may be of any type. For non-limiting examples, communications, Earth observation, space observation, weather forecasting, Internet of Things related hardware, materials experiments in the space environment, and navigation.

Step 422 includes testing the small satellite and analyzing the test data. Flaws found in testing may lead to redesign and new additive design and manufacturing. Testing may include, for non-limiting examples, bus control software, payload software, and performance and environmental tests of the components and subsystems.

Step 424 includes, without limitation, packing, crating, and transporting the satellite.

We claim:

1) A process for rapid re-configuration and customization of small satellites comprising the steps of:
a) providing an additive manufacturing facility;
b) providing a small satellite design facility in communication with said additive manufacturing facility;
c) receiving requirements for a small satellite in said small satellite design facility;
d) producing a bus design responsive to said received requirements, wherein said bus design comprises electronic bus elements;
e) producing a chassis design responsive to said received requirements, wherein said chassis design comprises adaptations to said bus elements and to a payload; and
f) additively manufacturing a small satellite chassis responsive to said received requirements.

2) The process of claim 1, comprising integrating said bus elements one of:
a) on sidewalls of said additively manufactured chassis; and
b) on frame portions of said additively manufactured chassis.

3) The process of claim 1, comprising integrating said bus elements as sidewalls on said additively manufactured chassis.

4) The process of claim 1, comprising integrating said payload with said chassis to form a small satellite.

5) The process of claim 4, comprising:
a) providing satellite testing facilities; and
b) testing said small satellite in said testing facility.

6) The process of claim 4, comprising:
a) providing a small satellite shipping facility; and
b) shipping said small satellite to a customer.

7) The process of claim 1, wherein said additive manufacturing facility comprises at least one three-dimensional printer.

8) The process of claim 1, wherein said additive manufacturing facility comprises a plurality of additive manufacturing devices each operable to additively manufacture said chassis using at least one of various materials.

9) The process of claim 1, wherein said producing a bus design comprises at least one of:
a) selecting a stored bus design from a database of bus designs;
b) customizing said stored bus design; and
c) creating a new bus design.

10) The process of claim 1, wherein said producing a chassis design comprises at least one of:
a) selecting a stored chassis design from a database of bus designs;
b) customizing said stored chassis design; and
c) creating a new chassis design.

11) A process for rapid re-configuration and customization of small satellites comprising the steps of:
a) providing an additive manufacturing facility;
b) providing a small satellite design facility in communication with said additive manufacturing facility;
c) receiving requirements for a small satellite in said small satellite design facility;
d) producing a bus design responsive to said received requirements, wherein said bus design comprises electronic bus elements;
e) producing a chassis design responsive to said received requirements, wherein said chassis design comprises adaptations to said bus elements and to a payload;
f) additively manufacturing a small satellite chassis responsive to said received requirements;
g) at least one of:
i) integrating said bus elements on sidewalls to said additively manufactured chassis;
ii) integrating said bus elements as sidewalls on said additively manufactured chassis; and
iii) integrating said bus elements on frame portions of said additively manufactured chassis.

12) The process of claim 11, comprising integrating said payload with said chassis to form a small satellite.

13) The process of claim 12, comprising:
a) providing satellite testing facilities; and
b) testing said small satellite in said testing facility.

14) The process of claim 12, comprising:
a) providing a small satellite shipping facility; and
b) shipping said small satellite to a destination.

15) The process of claim 11, wherein said additive manufacturing facility comprises at least one of:
a) a three-dimensional printer; and
b) a plurality of additive manufacturing devices each operable to additively manufacture said chassis using at least one of various materials.

16) The process of claim 11, wherein said producing a bus design comprises at least one of:
a) selecting a stored bus design from a database of bus designs;
b) customizing said stored bus design; and
c) creating a new bus design.

17) The process of claim 11, wherein said producing a chassis design comprises at least one of:
a) selecting a stored chassis design from a database of bus designs;
b) customizing said stored chassis design; and
c) creating a new chassis design.

18) A process for rapid re-configuration and customization of small satellites comprising the steps of:
a) providing an additive manufacturing facility;
b) providing a small satellite design facility in communication with said additive manufacturing facility;
c) receiving requirements for a small satellite in said small satellite design facility;
d) producing a bus design responsive to said received requirements, wherein said bus design comprises electronic bus elements;
e) producing a chassis design responsive to said received requirements, wherein said chassis design comprises adaptations to said bus elements and to a payload;
f) additively manufacturing a small satellite chassis responsive to said received requirements;
g) at least one of:
i) integrating said bus elements on sidewalls to said additively manufactured chassis;
ii) integrating said bus elements as sidewalls on said additively manufactured chassis; and
iii) integrating said bus elements on frame portions of said additively manufactured chassis; and
h) integrating said payload with said chassis to form a small satellite.

19) The process of claim 11, wherein said additive manufacturing facility comprises at least one of:
a) a three-dimensional printer; and
b) a plurality of additive manufacturing devices each operable to additively manufacture said chassis using at least one of various materials;
c) said producing a bus design comprises at least one of:
i) selecting a stored bus design from a database of bus designs;
ii) customizing said stored bus design; and
iii) creating a new bus design; and
d) said producing a chassis design comprises at least one of:
i) selecting a stored chassis design from a database of bus designs;
ii) customizing said stored chassis design; and
iii) creating a new chassis design.
